(19) United States
(12) Patent Application Publication
(10) Pub. No.: US 2002/0094684 A1
(43) Pub. Date: Jul. 18, 2002

(54) Foam cleaning process in semiconductor manufacturing

(76) Inventors: George J. Hirasaki, Bellaire, TX (US); Daniel Pham, Austin, TX (US)

Correspondence Address: CONLEY ROSE & TAYON, P.C., P. O. BOX 3267, HOUSTON, TX, 77253-3267, US

(21) Appl. No.: 09/995,044

(22) Filed: Nov. 27, 2001

Related U.S. Application Data
(60) Provisional application No. 60/253,332, filed on Nov. 27, 2000.

(51) Int. Cl. H01L 21/302; H01L 21/461

(52) U.S. Cl. 438/689; 438/691; 438/693

(57) ABSTRACT

A method and apparatus for cleaning semiconductor wafers during the fabrication process. In the method, a foam is passed over the wafer surfaces in order to remove particulate matter. Viscosity, electrical charge and recipe of the foam may be varied to enhance wafer cleaning. In a preferred embodiment of the present invention, a number of wafers are situated vertically in a cleaning chamber and allowed to rotate between a number of axially rotatable rollers, with at least one roller also being a drive roller, while foam is passed across the wafer surfaces.

### CROSS-REFERENCE TO RELATED APPLICATIONS

The present application claims benefit of priority from U.S. Ser. No. 60/253,332, filed Nov. 27, 2000, and entitled “Foam Cleaning Process in Semiconductor Manufacturing,” which is incorporated herein in its entirety.

### STATEMENT REGARDING FEDERALLY SPONSORED RESEARCH OR DEVELOPMENT

Not Applicable.

### FIELD OF THE INVENTION

The present invention relates generally to a method for cleaning semiconductor wafers during the fabrication process. In particular, the invention relates to a method for removing particles from the surface of semiconductor wafers by passing foam over the wafer surfaces. More specifically, the invention relates to a method for removing particles remaining on the wafer surface subsequent to chemical mechanical polishing or planarization (CMP) operation in the wafer fabrication process.

### BACKGROUND OF THE INVENTION

Modern-day semiconductor devices, commonly called microchips, are fabricated in nearly particle-free “cleanroom” environments using a multi-step process that constructs numerous devices on disc-shaped wafers. Due to the miniscule sizes of transistor circuitry on each device, it is critical to the fabrication process that the wafers remain as clean and particle-free as possible, as even tiny particles may lead to defects that render a device inoperable, consequently lowering yield and associated profits.

Critical to improving yield is raising the number of good devices per wafer. To accomplish this, the semiconductor industry is moving in the direction of larger-diameter wafers and smaller devices, so that more devices can be “squeezed” onto a single wafer. Also, more effective and efficient methods are sought for cleaning the wafers during the fabrication process.

One primary challenge in wafer cleaning is the continuing reduction of defect levels. Defects or particles potentially present on wafer surfaces include CMP slurry residue, oxides, organic contaminants, mobile ions and metallic impurities. Generally, a “killer defect” (particle) is less than half the size of the device linewidth. For instance, a device using 0.25-micron (μm) linewidth geometry, where a micron is one millionth of a meter, will require that cleaning steps remove particles smaller than 0.12 μm, and at 0.18 μm, cleaning must remove particles smaller than 0.09 μm. Due to their smaller size, it is physically more difficult to remove smaller particles than larger particles, since it is harder to deliver the needed force to such a minute area. Consequently, more energy or force is required to remove smaller particles.

As the number of transistors on a semiconductor device surpasses one billion, and transistor sizes on each device shrink to less than 0.1 μm, semiconductor device fabrication now demands new technology that can effectively remove particles without damaging the wafer. Because conventional wafer cleaning processes require large amounts of very clean water, it would also be advantageous to reduce the amount of water required for wafer cleaning. Wafer cleaning steps are performed after many steps in the fabrication process, including CMP, chemical vapor deposition (CVD), pre- and post-etch and diffusion.

As challenges mount with the advent of new technology and particle removal becomes more critical, advances must also be made in the area of wafer cleaning to keep pace with the demands of smaller devices. It is desired to provide a wafer cleaning process that is effective in removing increasingly smaller particles from wafer surfaces after a variety of operations. It is particularly desired to provide a wafer cleaning process that is effective for removing the particles that remain on the wafer surface after the CMP operation.

The CMP operation is utilized to remove excess coating material, reduce wafer topographical imperfections, and improve the depth of focus for lithography processes through better planarity. During the CMP operation, sub-micron-size particles from the associated polishing slurry are used to remove non-planar topographical features and extra coating on the wafer surface. After the CMP operation, these ultra-small slurry particles and particles from the polished material remain on the wafer surface. Typical rinsing is not sufficient to remove the particles to an acceptable cleanliness level.

Several prior art methods for post-CMP cleaning exist, the two most common being brush scrubbing and megasonic assist cleaning. Brush scrubbing is a mechanical contact, single-wafer cleaning process, also used for general particle reduction, wherein wafers are passed in succession through a cleaning chamber, where they are contacted with rotating brushes that deliver deionized (DI) water and cleaning chemicals to the wafer. Brush scrubbing has several drawbacks. One significant drawback is that the brush scrubbing technique tends to scratch the wafer by the mechanical contact and rotation of the brushes on the wafer surface.

In addition, the brush scrubbing method currently requires 8 to 12 liters of water per wafer cleaning. Water consumption in semiconductor manufacturing is a major concern, not only in this step in the manufacturing process, but throughout many operations of fabrication. Over the last decade, the semiconductor industry has worked to decrease water consumption in semiconductor manufacturing, especially in wafer cleaning operations. Early versions of wafer scrubbers using high-pressure water sprays and nylon brushes have been replaced by versions with low-pressure water sprays and gentler, sponge-like material brushes to reduce water consumption and wafer surface damage.

As device size shrinks with newer technology, the functionality of devices is increasing, as are the number of metal layers on each device. Semiconductor devices are built in layers, with many processes repeated as each layer is built up. As the number of layers increase, so do the associated processes, including cleaning operations. Therefore, as cleaning operations increase, it is crucial to reduce the complexity and the resources allocated to each cleaning operation.

Still another drawback to the brush scrubbing method is limited throughput. As this method is a single-wafer method requiring that the wafers pass through the brushes in a queued fashion, it is inherently not as effective as a method that could simultaneously clean several wafers at once.

Additionally, as the brush is a mechanical device that develops wear with use, the brush must be replaced frequently and also requires weekly preventive maintenance, procedures that add cost and downtime and reduce throughput in the overall fabrication process. Furthermore, the brush scrubbing method does not suspend particles removed from the wafer, so they may be redeposited by the brush or rinse onto the wafer later in the cleaning process.

As wafer diameters increase, warpage across these thin structures becomes more evident. Consequently, it is possible for certain sections of the wafer to not be contacted or cleaned by the scrubbing brush at all.

Furthermore, as wafers pass under the scrub brush, particles are swept away in one direction. Because of this, the brush scrubbing method is inherently less effective in removing particles trapped in miniscule grooves present on the wafer surface, since some of the grooved particles might have to be subjected to force in a different direction than that of the brush in order to be dislodged.

A second commonly used prior art cleaning method is megasonic assist cleaning. Megasonic assist cleaning is a single-wafer cleaning process wherein a megasonic transducer delivers sonic energy to loosen particles on a wafer surface that is being sprayed by water or a cleaning liquid.

As with brush scrubbing, megasonic assist cleaning has limited throughput, does not trap particles in a medium so that they cannot be redeposited onto the wafer later, and requires a lot of water. While this method requires less water than brush scrubbing, megasonic assist cleaning still requires some 6 to 8 liters of water per wafer cleaning. Although megasonic assist cleaning is non-contact and does not mechanically damage the wafer surface by its cleaning method, vibration associated with megasonic energy has the potential to damage delicate device fixtures.

In addition to the disadvantages identified above, as wafer sizes grow and device sizes and associated transistor sizes shrink, the existing methods are becoming less effective, as increasingly smaller particles will be able to cause killer defects. As a result, a method for removing particles from the whole surface of a wafer in a cost-effective and environmentally friendly manner must be addressed.

Other known cleaning methods, including laser cleaning, which uses lasers to lift particles from the wafer surface and inert gas sprays to blow the particles from the wafer surface, and various other spray methods, including air sprays and water jets, are all plagued by recontamination issues.

Hence, no existing cleaning method comprehensively addresses recontamination, warpage inherent to larger wafer diameters, embedded defect removal, water consumption, wafer damage and throughput issues.

### SUMMARY OF THE INVENTION

It is an object of the present invention to provide a non-contact foam wafer cleaning method designed to eliminate the abovementioned drawbacks and to meet the challenges of emerging technologies in the semiconductor market.

Another object of the invention is to provide an effective method for removing small particles from the surface of a wafer more effectively than prior art methods by increasing the sheer stress of the cleaning medium, therefore increasing the amount of force on the particles.

Another object of the invention is to provide an effective method for post-CMP wafer cleaning without direct mechanical wafer surface contact, thereby preventing physical damage to the wafer by the cleaning process.

Another object of the invention is to lessen environmental effects of wafer cleaning by reducing water consumption and surfactant usage.

Another object of the invention is to provide an efficient method for post-CMP wafer cleaning by utilizing a batch-clean process, wherein multiple wafers can be cleaned simultaneously, increasing throughput and production efficiency.

Another object of the invention is to reduce production downtime by omitting contact mechanical cleaning devices which develop wear and need frequent replacement, such as the brushes used in the brush scrubbing method.

Another object of the invention is to reduce production costs by omitting contact mechanical cleaning devices which develop wear and need frequent replacement, such as the brushes used in the brush scrubbing method.

Another object of the invention is to reduce redeposition of particles onto the wafer by a brush by eliminating this part from the cleaning method.

Another object of the invention is to provide a means for suspending lifted particles in a medium to prevent cross-contamination of the wafer during removal.

Another object of the invention is to eliminate the effects of wafer warpage on the cleaning process.

Another object of the invention is to develop an effective method for removing particles trapped in miniscule grooves present on the wafer surface.

Another object of the invention is to provide a method of wafer cleaning without the harmful effects of vibration.

Another object of the invention is to provide a method for cleaning semiconductor wafers with foam of variable electrical charge, so as to use attraction to lift particles from the wafer.

Another object of the invention is to provide a method for cleaning semiconductor wafers with foam of variable viscosity.

Another object of the invention is to provide a method for cleaning semiconductor wafers with foam of variable surfactant recipe.

Another object of the invention is to provide a method for cleaning semiconductor wafers with a flexible setup capable of cleaning wafers in vertical, horizontal or other orientation, as well as in batch or single-wafer process, depending on the setup of adjacent tools.

As the semiconductor industry moves toward 300 mm technology and beyond, it is becoming necessary to develop an innovative wafer cleaning process that addresses the shortcomings of the prior art methods and the critical needs of 300 mm technology, emerging copper development, sub-0.25 μm and flat panel display technologies. Addressing those requirements, foam cleaning is the most effective and environmentally friendly method of removing particles. This non-contact and non-energy cleaning process does not depend on wafer size or shape and will not effect damage on the wafer surface. The high-throughput batch-cleaning process also will reduce CO₂, chemical and water consumption.

Hence, the present invention includes a method for removing particles from a wafer surface, comprising passing a foam across the wafer surface. The method provides good wafer cleaning without necessitating direct mechanical wafer surface contact. If desired, the foam cleaning step can be repeated using a second foam, with the second foam being different from the first foam, with a rinse, or with another material.

The invention also includes a preferred apparatus for removing particles from a wafer surface, comprising a wafer support, a foam source capable of generating a foam, and at least one foam guide defining a gap with the wafer surface. A foam flow path is provided for said foam from said foam source across the wafer surface and a means for rotating the wafer(s) is preferably provided so as to ensure uniform cleaning.

### BRIEF DESCRIPTION OF THE DRAWINGS

For a more detailed description of the preferred embodiment of the present invention, reference will now be made to the accompanying drawings, wherein:

FIG. 1 is a cross-sectional view of a wafer surface with typical particulate matter, along with foam flowing over the wafer surface in accordance with the present invention;

FIG. 2 is a side view of a stack of wafers in a cleaning device constricted in accordance with a preferred embodiment of the present invention, wherein a number of wafers are situated vertically and allowed to rotate, so that foam will uniformly pass over their respective surfaces;

FIG. 3 is an end view, with respect to a stack of wafers, of a preferred embodiment of the present invention, wherein a wafer is constrained between a number of axially rotatable, grooved rollers;

FIGS. 4A and 4B are side views, respectively, of a wafer subjected to the prior art brush scrubbing method and a wafer subjected to the foam clean method of the present invention;

FIG. 5 is an end view, with respect to a stack of wafers, of an alternate preferred embodiment of the present invention, wherein a wafer is constrained between a number of axially rotatable, grooved rollers.

### DETAILED DESCRIPTION OF THE PREFERRED EMBODIMENT

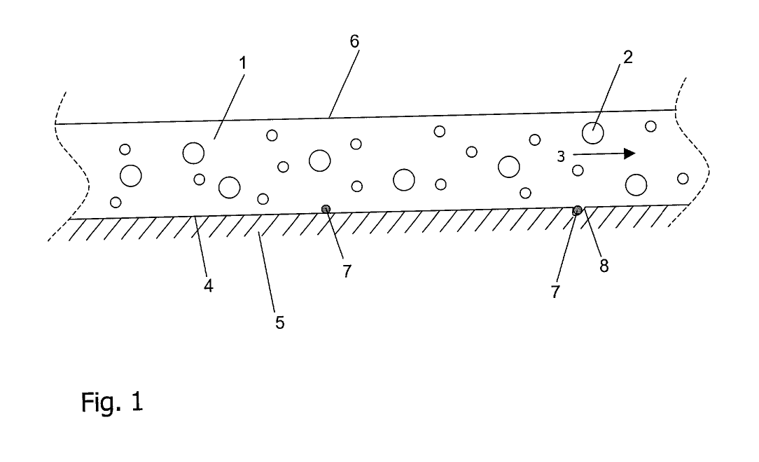

The present invention provides a novel and highly effective method and apparatus for removing undesired particles from a wafer surface. According to a preferred embodiment, a viscous foam is pumped across the wafer surface, entraining and removing the particles in the process. By way of illustration, reference numeral 1 in FIG. 1 indicates a foam comprised of bubbles 2 moving in a direction 3 across the surface 4 of a wafer 5. Foam 1 is bound on one side by wafer surface 4 and on the other side by a boundary, or foam guide, 6, which may or may not be an adjacent wafer surface 4. Foam 1 serves to remove a particle 7 from wafer surface 4, sweeping it from wafer surface 4 and suspending it amid bubbles 2. Foam 1 can also act to lift and suspend a particle 7 trapped in a groove-like defect 8 on the wafer surface 4.

Ideally, wafer surfaces 4 are free from defects or topographical irregularities. However, on a microscopic basis, grooves 8 and other such defects can exist. Cleaning tiny particles 7 from such a groove 8 is a difficult task for conventional cleaning methods for many reasons, such as the limitations of unidirectional cleaning, inadequate force, and the inability to reach into grooves. Prior art cleaning methods already have shortcomings when it comes to removing the miniscule particles that will cause killer defects in the future. Removing these increasingly small particles 7 from grooves 8 is already difficult and will only get more difficult when the size of particles 7 requiring removal continues to shrink.

When such a small particle 7 is lodged in a groove 8, removing the particle 7 becomes much more difficult than removing it from a planar surface. Foam cleaning has the advantage in such a case over prior art methods because foam 1 possesses no rigid cleaning structure and, because of its viscosity, can conform tightly to the wafer surface 4, no matter the topography. Additionally, the present invention allows for the rotation 26 of wafers 5 during the cleaning process. Therefore, a particle 7 that cannot be dislodged by foam 1 passing over it in one direction will be subjected to flow of foam 1 from a variety of angles before the wafer 5 completes the cleaning cycle.

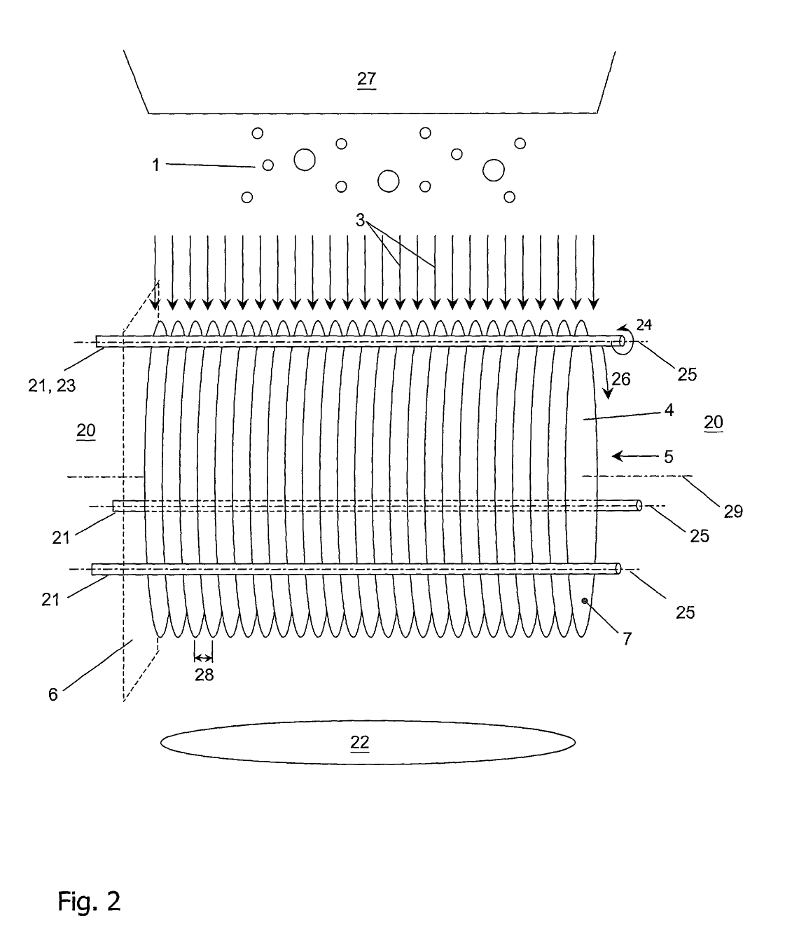

While the apparatus design for applying the desired foam cleaning method is not critical, the preferred embodiment shown in FIG. 2 helps to clearly demonstrate the method claimed by the present invention. FIG. 2 shows in side view a number of wafers 5 situated at a distance 28 from each other within a process chamber 20 supported by a number of axially rotatable grooved rollers 21 and above a drainage chamber 22. Foam 1 is flows into chamber 20 from a foam source 27. If desired, a manifold, diffuser, or other device can be provided between foam source 27 and chamber 20 to provide a distributed flow of foam, as shown at 3. After entering chamber 20, foam 1 flows between the wafers 5, guided by adjacent wafer surfaces 4, and, on the end wafers, by wafer surface 4 of the end wafer and by a boundary 6, which could be a wall of process chamber 20.

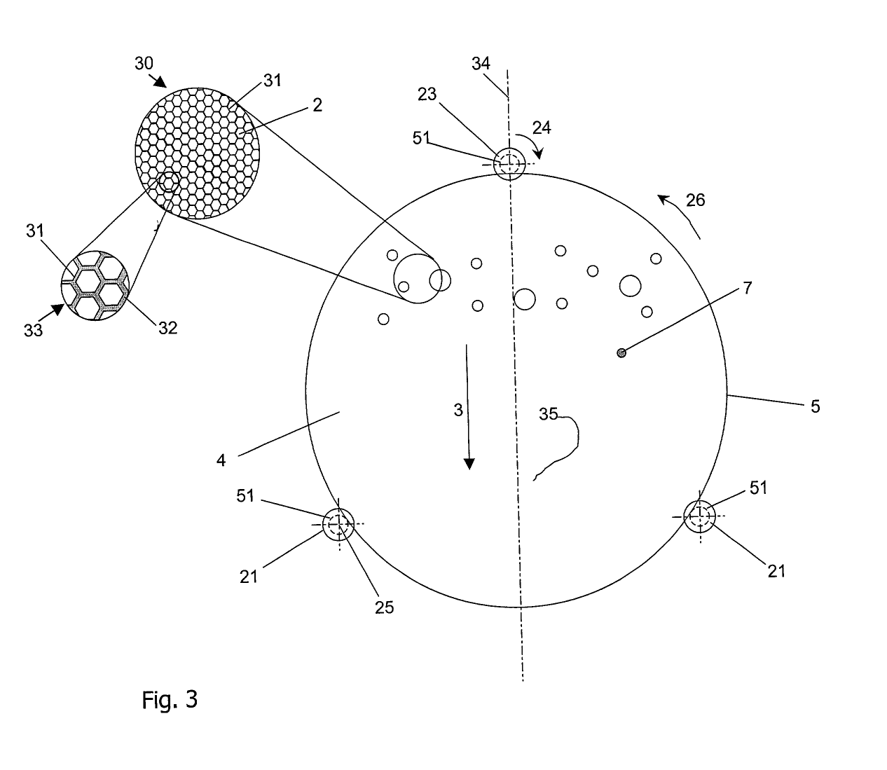

As best shown in FIG. 3, rollers 21 each preferably include a plurality of circumferential grooves 51. Grooves 51 receive the edges of wafers 5 and are therefore preferably aligned so that the plurality of wafers 5 is supported in parallel fashion.

Still referring to FIG. 3, in a preferred embodiment, at least one roller 21 may also be a drive roller 23 rotating in a direction 24, causing rotation 26 of wafers 5 in the opposite direction about their respective center axes 28. Rotation 26 of wafers 5 in turn causes the other rollers 21, which are preferably freely rotating, to rotate about their respective center axes 25. An area of maximum shear 35 exists along a line 34 between the foam entrance opening and the foam exit opening (both not shown). Rotation 26 ensures that all areas of wafers 5 are subjected to this area of maximum shear 35. Foam 1 passes over the surface 4 of wafer 5 in direction 3, in the process lifting and entrapping particles 7. Number 30 is a close-up of a possible structure of bubbles 2 showing lamellae 31, or shared walls between adjacent bubbles 2. It is possible for an amount of liquid 32 to be present between lamellae 31, as shown in number 33.

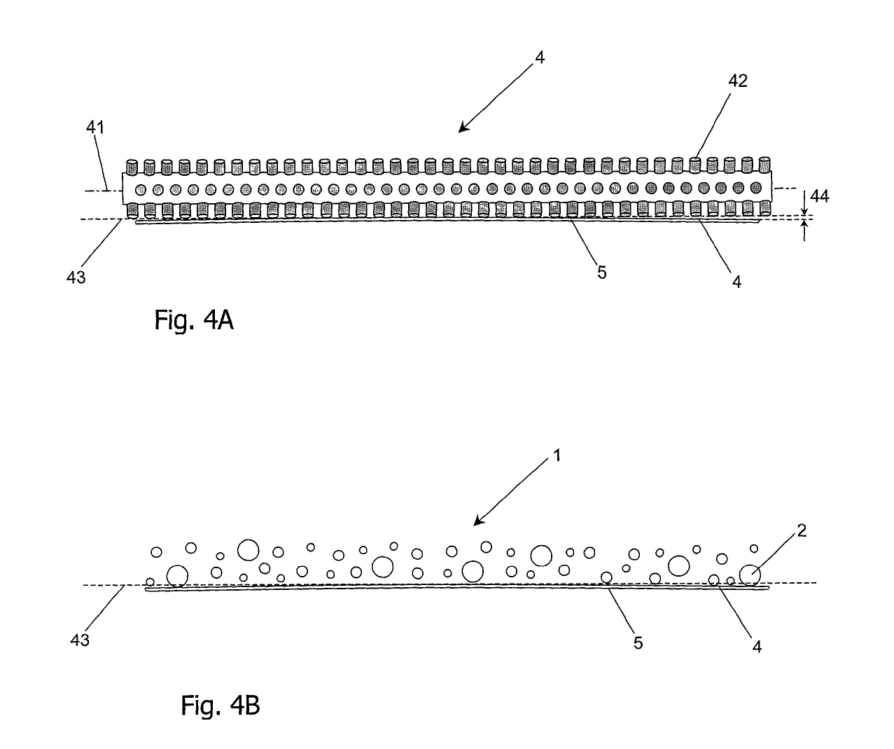

FIG. 4A shows a brush scrubbing apparatus 40 which rotates about its central axis 41 to contact surface 4 of wafer 5 with brush heads 42. As the technology roadmap in semiconductor manufacturing moves toward larger-diameter wafers, warpage over these very thin, wide structures becomes of greater concern. For example, warpage that was negligible in a 200-mm-diameter wafer can be significant when seen on a 300-mm-diameter wafer.

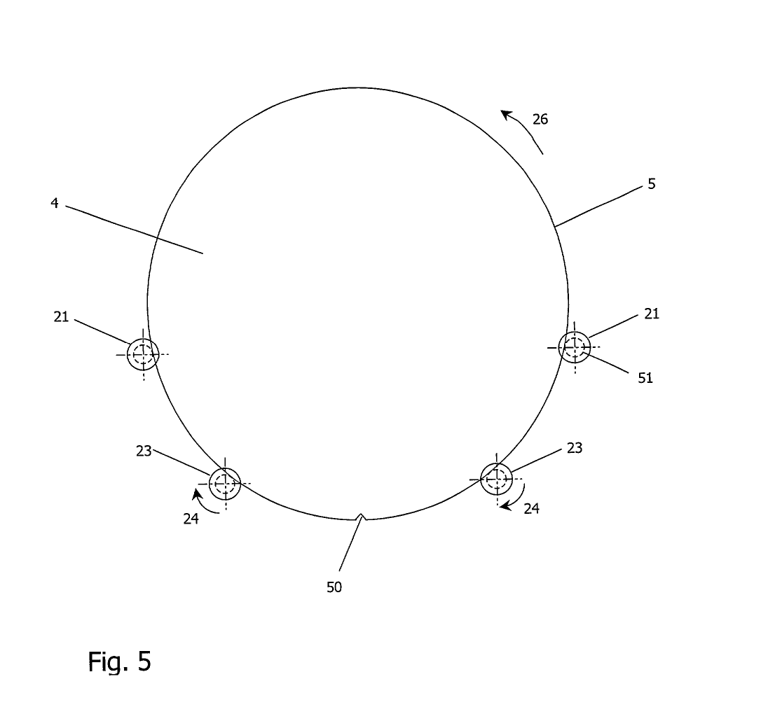

FIG. 5 shows a variation of the preferred embodiment of FIG. 3, wherein more than one axially rotatable roller 21 is also a drive roller 23. Number 50 in FIG. 5 represents an alignment notch typically present on wafers 5. Depending on the diameter(s) of the rollers that are used, it may be beneficial to include more than one drive roller 23, so that a second roller can assist wafer rotation 26 when one drive roller 23 encounters alignment notch 50 during rotation of wafers 5.

Cleaning methods that rely on a rigid structure contacting a planar surface, as with the brush scrubbing method, will inherently be less effective than a cleaning method that can conform to any curve or irregularity on the wafer surface 4. Referring again to FIG. 4A, reference numeral 43 represents the horizontal top plane of a “perfect” unwarped wafer. The gap shown by number 44 represents the distance between brush heads 42 and warped wafer surface 4, so it can be seen that the brush heads 42 on the ends of the scrubbing apparatus 40 will have difficulty contacting the outer edges of wafer 5.

FIG. 4B illustrates how the foam cleaning method of the present invention can overcome such obstacles. While brush heads 42 cannot reach into gap 44, bubbles 2 of foam 1 are able to conform to wafer surface 4, as if it were perfectly aligned with horizontal 43. Consequently, the effects of surface warpage, which threatens to afflict larger-diameter wafers in the future, can be alleviated in cleaning steps by the present invention.

There are several variables that contribute to the cleaning capability of foam 1, but essentially, the cleaning capability is directly related to the shear stress exerted by foam 1 on wafer surfaces 4. Higher shear stress imparts the needed force to lift very small particles 7 from the wafer surfaces 4. Foam for the intended cleaning method would range roughly from 100 to 10,000 times the viscosity of water, which is roughly 1 centipoise at room temperature, with the higher viscosity foam being more effective for wafer cleaning.

The shear stress on the wafer surface 4 is controlled by the flow, gap width 28, and apparent viscosity of the foam. The flow field will be a Hele-Shaw flow, or forced flow between parallel plates. Maximum shear stress will be along the line 34 between the entrance and exit. The rotation of the wafers 5 will result in all parts of the wafers 5 passing through the area of maximum shear 34.

Several known techniques for mechanically or chemically generating foam 1 can be used in the present invention. One standard way of creating a foam is to inject a pressurized gas and a liquid through a porous surface in a device called a frit. For the purposes of this invention, the liquid preferably comprises a mixture of DI water and a commercially available surfactant, with the preferred recipe of foam 1 being 0.1%-0.5% ammonium dodecyl(3EO)sulfate, which can be varied depending on cleaning needs.

Foam 1 can be formed from a gas, such as air or an inert gas, that is non-reactive with the surfactant. Foam 1 can be alternately be formed from a gas mixture including a non-reactive component and a reactive component which reacts with the surfactant solution to alter the pH and/or foam surface potential.

Foam texture is variable, and is a measure of the size of bubbles 2. A finer foam 1 has smaller bubbles 2, and therefore, more lamellae 31 per unit length, making its resistance to flow greater. Thus, smaller bubbles 2 equate to a higher apparent viscosity. By reducing pore size in the frit, finer bubbles 2, and therefore, more viscous foam 1 can be obtained. The gas content of foam 1 would typically range from 90 to 99 percent. Foam 1 becomes more viscous with increasing gas fraction until foam 1 starts to break.

Addition of a polymer is one way to alter the viscosity of foam 1. Polyacrylic acid of about 5×10⁶ molecular weight (Mw) will be effective in both increasing viscosity and suspending positive particles at concentrations of about 0.1%.

Another variable that can alter the cleaning capability of foam 1 is the gap 28 between wafers 5. As previously stated, a smaller gap 28 contributes to a higher shear stress, so in one preferred embodiment the wafers 5 are cleaned in a batch process. In the batch process, wafers 5 are preferably closely aligned, as they are in a wafer cassette between fabrication steps, as illustrated generally in FIG. 2. Gap 28 could be varied to increase or decrease apparent viscosity, as needed. By positioning wafers 5 in close proximity to one another, a Hele-Shaw flow field is induced in the parallel gaps 28 between the wafers 5. For the purposes of this invention, the optimal gap 28 between wafers is less than 0.25 inches, or 0.635 centimeters, wide.

An additional advantage to the method claimed by the present invention is that, while the aforementioned batch cleaning process enjoys the benefits of increased throughput, the foam cleaning method could be carried out in a variety of wafer orientations and tooling setups. For instance, depending on the setup of the fabrication tool immediately preceding the foam clean step, wafers 5 may be oriented horizontally, vertically, or in any number of other orientations, since their surfaces 4 can be completely enveloped in foam 1, regardless of their orientation. Additionally, if multi-wafer batch processing is not desired, such as if the tool preceding the foam clean step does not handle multiple wafers 5 at once, the present foam cleaning method can be used equally effectively on a single wafer 5. Hence, the effectiveness of the cleaning method is independent of orientation or quantity of wafers cleaned.

As different fabrication steps will result in different types of particles 7 needing to be cleaned from wafer surfaces 4, an additional feature of the present method allows for the gas/liquid interfaces of the bubbles that make up the foam, or the internal lamellae structure of foam 1 itself, to have an electrical charge. The charge of foam 1 is preferably opposite to that of particles 7 to be removed. These respective charges vary depending on process used. Hence, for example, a cleaning process can be run using a cationic surfactant such as hexadecyltrimethylammonium chloride to attract and trap negatively charged particles 7 such as silica, and for an anionic surfactant such as dodecylether sulfate to attract and trap positively charged particles 7 such as alumina. This difference in electrical charge assists in the prevention of particle redeposition onto wafer surface 4 by using electrical charge to hold particles 7 away from wafer surface 4, aiding the suspension properties inherent to the foam 1 structure itself.

As device circuitry becomes smaller, the size of particles 7 that can ruin a circuit also becomes smaller, so as technology advances, it is becoming increasingly critical to adopt a wafer cleaning method that effectively removes these smaller particles 7. Defects that were once considered unimportant because they were too small to be considered “killer defects” will be considered as such when chip circuitry shrinks accordingly. Since reduction of defects is a key ongoing pursuit in semiconductor fabrication, it is crucial to the industry to look ahead for methods that will target increasingly smaller particles 7.

Brush scrubbing, a common post-CMP wafer cleaning method used in industry today, decreases in effectiveness as particle size decreases for several reasons. Brush scrubbing serves to remove particles 7 from wafer surfaces 4 by contacting them with whirling sponge-like brush heads 42 that deliver DI water and cleaning chemicals to the wafer surface 4. As particle sizes 7 shrink, it is more and more difficult for a brush head 42 to deliver the necessary force to such a small dimension. Foam cleaning circumvents this problem since the viscosity of the foam 1 itself, and hence, its shear stress imposed on a particle 7 can be increased as needed to effectively remove very small particles 7.

Foam cleaning also avoids another major drawback of the brush scrubbing method, namely mechanical damage. Since brush scrubbing cleans by mechanical contact of high-revolution brushes 40, damage can be inflicted on the delicate wafer surface 4 by either the brush heads 42 themselves or by particles 7 already lifted by brush heads 42 but not yet evacuated. Foam cleaning is a much gentler cleaning process by comparison, contacting the wafer surfaces 4 with no mechanical parts, only viscous foam 1. Consequently, the force on particles 7 can be increased without worry of damaging the wafer surface 4 itself.

With high-volume wafer fabs starting dozens of thousands of wafers per week, resource usage and costs are closely monitored. For the common 200-mm-diameter wafer, post-CMP cleaning using the brush scrubbing method generally uses 8 to 12 liters of water per wafer 5. Foam cleaning would diminish the environmental impact and associated costs by reducing the amount of water used in post-CMP cleaning.

Advancing technology means the shrinking of device sizes, an increase in device functionality, and an increase in the number of metal layers on each device. Semiconductor devices are built in layers, with many processes repeated as each layer is constructed. As metal layers increase, so do the number of post-CMP cleaning steps. As a result, it is important to reduce the complexity and the resources allocated to each cleaning step.

Another benefit of foam cleaning over brush scrubbing is its applicability to batch processes. Brush scrubbing is a single-wafer method requiring wafers 5 to pass through the cleaning chamber in a queued fashion. As previously mentioned, foam cleaning can be applied effectively to either clean a single wafer 5 or several wafers 5 at once, increasing manufacturing throughput.

An additional shortcoming of the brush scrubbing method is that the brush 40 is a mechanical device that develops wear with use and must be replaced frequently. This requirement adds material and labor costs and increases equipment downtime, reducing manufacturing throughput in the process. Time that is “down to production” on a tool is tracked very carefully in a wafer fab environment, so as to maximize production output. Also significant is the regular preventive maintenance required for the brush scrubbing apparatus 40, a procedure that is generally longer in duration the more mechanically complex a tool is. Since the foam clean method is effectively non-contact where mechanical devices are concerned, there is no mechanical device to replace on a frequent basis, thus saving replacement costs and tool downtime.

Redeposition of particles 7 on the wafer surface 4 is a problem with the brush scrubbing method. As the brush cannot suspend particles 7 lifted from the wafer surface 4, it is possible for particles 7 to be redeposited by the brush 40 or rinse back onto the wafer surface 4 later in the cleaning process. Foam cleaning solves this problem by the structure of foam 1 itself. In the present invention, foam 1 serves to lift particles 7 from the wafer surface 4 and suspend them within its structure, preventing them from redepositing onto wafer surface 4 using electrostatic attraction force between particle 7 and bubbles 2. Foam 1 preferably has a greater opposite charge to particle 7 than does wafer surface 4, which makes the electrostatic attraction force between particle 7 and foam 1 higher than that between particle 7 and wafer surface 4.

The other commonly used prior art cleaning method, megasonic assist cleaning, suffers from many of the same disadvantages as does brush scrubbing. Both are typically single-wafer processes that limit throughput, and while megasonic assist cleaning requires less water than does brush scrubbing, at 6 to 8 liters of water per wafer, this is still a significant amount of water. While megasonic assist cleaning is non-contact and does not mechanically damage the wafer surface 4, vibration intrinsic to the megasonic energy tends to damage delicate device fixtures on the wafer surface 4.

Foam cleaning requires no such energy to perform wafer cleaning, relying mainly on the viscosity and properties of foam 1 itself After foam cleaning, wafers 5 may rinsed with DI water or a solution such as dilute alcohol and dried under a heated or non-heated inert gas, an organic solvent gas or a mixture of inert gas and an organic solvent gas. Alternatively, any other suitable method for removing the foam can be used, provided it does not damage the wafers or result in the re-depositing of particles on the wafer surfaces.

Several other prior art methods exist for wafer cleaning, including laser cleaning, inert gas sprays, air sprays and water jets, but none can adequately address the needs of wafer cleaning for semiconductor technologies of the future, such as larger wafers and smaller killer defects. Addressing those requirements, foam cleaning is the most comprehensively effective and environmentally friendly method of wafer cleaning subsequent to CMP, CVD and other fabrication operations.

Foam cleaning is a non-contact, low-energy, cleaning process that is independent of wafer size or shape, so it may be relied upon in the future for cleaning after a number of fabrication operations as further developments take place in wafer structure and defect reduction. Foam cleaning also will not inflict damage on the wafer surface. The high-throughput batch-cleaning process also will reduce CO₂, chemical and water consumption, making it a very attractive option from an environmental and economic standpoint.

What is claimed is:

1. A method for removing particles from a wafer surface, comprising:
passing a foam across the wafer surface.

2. The method according to claim 1 carried out in the absence of direct mechanical wafer surface contact.

3. The method according to claim 1 carried out in the absence of induced vibration.

4. The method according to claim 1 wherein the foam has a viscosity between 100 and 10,000 centipoise.

5. The method according to claim 1 wherein the foam has a viscosity between 100 and 10,000 times that of water.

6. The method according to claim 1 wherein the foam traversing the wafer surface is constrained between the wafer surface and a second surface.

7. The method according to claim 6 wherein the second surface is a second wafer.

8. The method according to claim 6 wherein the second surface is a chamber wall.

9. The method according to claim 6 wherein the wafer surface and the second surface define a gap therebetween and the gap is less than 0.25 inches (0.635 centimeters) wide.

10. The method according to claim 1 wherein the foam comprises a mixture of water and a surfactant.

11. The method according to claim 1 wherein the foam is formed from a gas that is nonreactive with the surfactant.

12. The method according to claim 1 wherein the foam is formed from a gas mixture that includes a non-reactive component and a reactive component that reacts with the surfactant solution to alter the pH and/or foam surface potential.

13. The method according to claim 1 wherein the interfaces of the foam have an electrical charge opposite to that of the particle being removed.

14. The method according to claim 1, further including repeating the foam cleaning step with a second foam, the second foam being different from the first foam.

15. The method according to claim 1, further including rotating the wafer.

16. The method according to claim 1, further including rotating the wafer at least 360 degrees.

17. An apparatus for removing particles from a wafer surface, comprising;
a wafer support;
a foam source capable of generating a foam;
at least one foam guide defining a gap with the wafer surface, and thereby providing a foam flow path for said foam from said foam source across the wafer surface.

18. The apparatus according to claim 17 wherein said foam has a viscosity between 100 and 10,000 centipoise.

19. The apparatus according to claim 17 wherein said foam has a viscosity between 100 and 10,000 times that of water.

20. The apparatus according to claim 17 wherein said foam guide is a second wafer.

21. The apparatus according to claim 17 wherein said foam guide is a chamber wall.

22. The apparatus according to claim 17 wherein said gap is less than 0.25 inches (0.635 centimeters) wide.

23. The apparatus according to claim 17 wherein said foam comprises a mixture of water and a surfactant.

24. The apparatus according to claim 17 wherein said foam is formed from a gas that is non-reactive with said surfactant.

25. The apparatus according to claim 17 wherein said foam is formed from a gas mixture including a non-reactive component and a reactive component that reacts with said surfactant solution to alter the pH and/or foam surface potential.

26. The apparatus according to claim 17 wherein the interfaces of said foam have an electrical charge opposite to that of the particle being removed.

27. The apparatus according to claim 17, further including a rotatable wafer support system for rotating the wafer during cleaning.

28. A method for removing particles from a wafer surface, comprising:
passing a foam across the wafer surface, wherein the foam has a viscosity between 100 and 10,000 centipoise, and wherein the foam traversing the wafer surface is rained between the wafer surface and a second surface, the wafer surface and the second surface defining a gap therebetween, the gap being less than 0.25 inches (0.635 meters) wide.

29. The method according to claim 28 wherein the second surface is a second wafer.

30. The method according to claim 28 wherein the interfaces of the foam have an electrical charge opposite to that of the particle being removed.
